(19) United States
(12) Patent Application Publication
(10) Pub. No.: US 2025/0278545 A1
(43) Pub. Date: Sep. 4, 2025

(54) PROGRAMMABLE AND SCALABLE BIT-SLICED VLSI ARCHITECTURE FOR DECISION TREE BASED MACHINE LEARNING EDGE INFERENCE

(71) Applicant: UNIVERSITY OF SOUTH FLORIDA, Tampa, FL (US)

(72) Inventors: Srinivas KATKOORI, Tampa, FL (US); Raaga Sai SOMESULA, Tampa, FL (US)

(21) Appl. No.: 19/069,154

(22) Filed: Mar. 3, 2025

Related U.S. Application Data
(60) Provisional application No. 63/560,281, filed on Mar. 1, 2024.

(51) Int. Cl. G06F 30/392; G06N 5/01

(52) U.S. Cl. CPC G06F 30/392; G06N 5/01

(57) ABSTRACT

Methods and systems are provided herein for a decision tree layout model. A method for imprinting a decision tree layout model onto a classification chip includes receiving a plurality of target model requirements. One or more decision tree-based inference models are loaded based on the plurality of target model requirements. Training data is obtained. The one or more decision tree-based inference models are trained using a depth layer. Predictions corresponding to the training data are generated using the one or more decision tree-based inference models. Prediction parameters associated with the plurality of predictions is determined. The prediction parameters are compared to the target model requirements. An inference model is selected from the one or more decision tree-based inference models, based on the comparison. A transistor layout is generated based on the selected inference model.

### CROSS-REFERENCE TO RELATED APPLICATION(S)

This application claims priority to U.S. Provisional Patent Application Ser. No. 63/560,281 filed Mar. 1, 2024 and U.S. Provisional Patent Application Ser. No. 63/713,824 filed Oct. 30, 2024, the content of which is hereby incorporated by reference in its entirety.

### STATEMENT REGARDING FEDERALLY SPONSORED RESEARCH

N/A

### BACKGROUND

The term “Internet of Things” (IoT) describes how everyday objects and machinery, such as buildings, cars, and furniture, are connected to the internet or to one another. The drive behind IoT stems from its potential to streamline operations, increase automation, and facilitate data-driven decision-making in various sectors. It's ability to connect physical devices to the internet offers advantages such as more efficient processes, reduced operational expenses, the gathering of extensive data for predictive maintenance, improved resource utilization, and enhanced safety and security. It offers opportunities to reduce environmental impact through optimized resource management. Despite the transformative potential of the IoT, it presents a myriad of challenges. One significant hurdle is the issue of latency, where delays in data processing can hinder the real-time responsiveness expected from IoT applications. Coping with the rapid increase in connected devices may utilize a robust infrastructure. Bandwidth constraints pose another challenge, particularly as the volume of data generated by IoT devices at the edge (by sensors) increases.

Edge computing is the practice of gathering, analyzing, and processing data at or near its point of generation to support local decision-making, reduce network traffic and congestion, and enable quicker and more efficient data transport. It arises as a strategic approach to address the difficulties encountered by conventional cloud-based processing in the context of IoT. It reduces latency, improves real-time processing, and mitigates bandwidth limitations by dispersing computing capacity across the network.

As the volume and diversity of data generated by IoT devices continue to grow, there is a compelling need for intelligent data processing at the edge. ML plays a pivotal role in this context by providing the capability for data filtering and informed decision-making. The idea of “ML on edge” implies an approach that enables the direct application of ML models to edge devices. By deploying ML algorithms on edge devices as in FIG. 1, data can be analyzed locally, reducing the need for extensive data transfers to centralized servers. This not only addresses the challenges of latency and bandwidth but also enables swift and context-aware decision-making directly at the source. Because edge machine learning can filter out irrelevant data and make decisions based on the relevant data that is accessible, it is particularly useful when network bandwidth is limited. For example, wearable technology may use edge machine learning to identify certain activities while eliminating noise. TensorFlow Lite and other machine learning frameworks can aid in the efficient deployment of machine learning models on edge devices. It is becoming more and more important to implement ML models directly on specialized hardware, such as Application Specific Integrated Circuits (ASICs), to guarantee quick answers in real-time applications.

The design of classifiers that can be embedded in a chip and need extremely little computational and memory resources is crucial for edge computing in cutting-edge industries such as smart agriculture and medical devices. Besides, to comply with strict power constraints, ML capabilities must be included in integrated circuits rather than depending on power-hungry FPGA-based microprocessors in mobile or implantable devices. This work aims to provide a custom ASIC architecture for DT model implementation on edge hardware.

### SUMMARY

In some aspects, the present disclosure can provide a method of imprinting a decision tree layout model onto a classification chip. A plurality of target model requirements can be received. One or more decision tree-based inference models can be loaded based on the plurality of target model requirements. Training data can be obtained. The one or more decision tree-based inference models can be trained using a depth layer D. A plurality of predictions corresponding to the training data can be generated using the one or more decision tree-based inference models. A plurality of prediction parameters associated with the plurality of predictions can be determined. The plurality of prediction parameters can be compared to the plurality of target model requirements. The depth layer D can be incremented upon determining that the plurality of prediction parameters do not meet the plurality of target model requirements. An inference model can be selected from the one or more decision tree-based inference models, based on the comparison. A transistor layout can be generated based on the selected inference model.

In some aspects, the present disclosure can provide a classification chip for performing a decision-tree prediction model. The chip can include a real-time block and a plurality of bit-slices. Each bit slice of the plurality of bit-slices can include a pair of 8-bit shift registers, a pair of 2-input AND gates, an 8-bit comparator, a first 8-bit multiplexer, and a second 8-bit multiplexer. The pair of 8-bit shift registers can receive a first input. The pair of 2-input AND gates can receive a clock signal and a second input. The 8-bit comparator can be connected to the pair of 8b-bit shift registers and can compare a first output from the pair of 8-bit registers. The first 8-bit multiplexer can be connected to the 8-bit comparator and can define a plurality of true and false paths. The second 8-bit multiplexer can be connected to the first 8-bit multiplexer and one 8-bit shift register of the pair of 8-bit shift registers. The second 8-bit multiplexer can define a plurality of classification labels.

These and other aspects of the disclosure will become more fully understood upon a review of the drawings and the detailed description, which follows. Other aspects, features, and embodiments of the present disclosure will become apparent to those skilled in the art, upon reviewing the following description of specific, example embodiments of the present disclosure in conjunction with the accompanying figures. While features of the present disclosure may be discussed relative to certain embodiments and figures below, all embodiments of the present disclosure can include one or more of the advantageous features discussed herein. In other words, while one or more embodiments may be discussed as having certain advantageous features, one or more of such features may also be used in accordance with the various embodiments of the disclosure discussed herein. Similarly, while example embodiments may be discussed below as devices, systems, or methods embodiments it should be understood that such example embodiments can be implemented in various devices, systems, and methods.

### BRIEF DESCRIPTION OF THE DRAWINGS

FIG. 1 is a flowchart illustrating an example process for generating a decision tree layout model, according to some embodiments.

FIG. 2 is a block diagram conceptually illustrating a system for implementing a decision tree inference model on a chip, according to some embodiments.

FIG. 3 is an example edge computing device system, according to some embodiments.

FIG. 4 is an example process illustrating a machine learning process on an edge device, according to some embodiments.

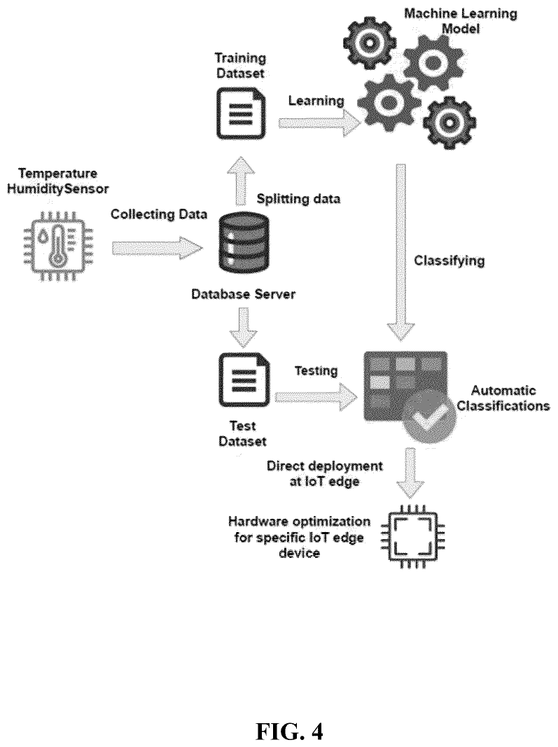

FIG. 5 is a diagram illustrating an example learning system model, according to some embodiments.

FIG. 6 is a diagram illustrating an example supervised learning model, according to some embodiments.

FIG. 7 is a diagram illustrating an example decision tree process, according to some embodiments.

FIG. 8 is a diagram illustrating an example decision tree implementation process, according to some embodiments.

FIG. 9 is an example process flow diagram for determining the accuracy of a decision tree, according to some embodiments.

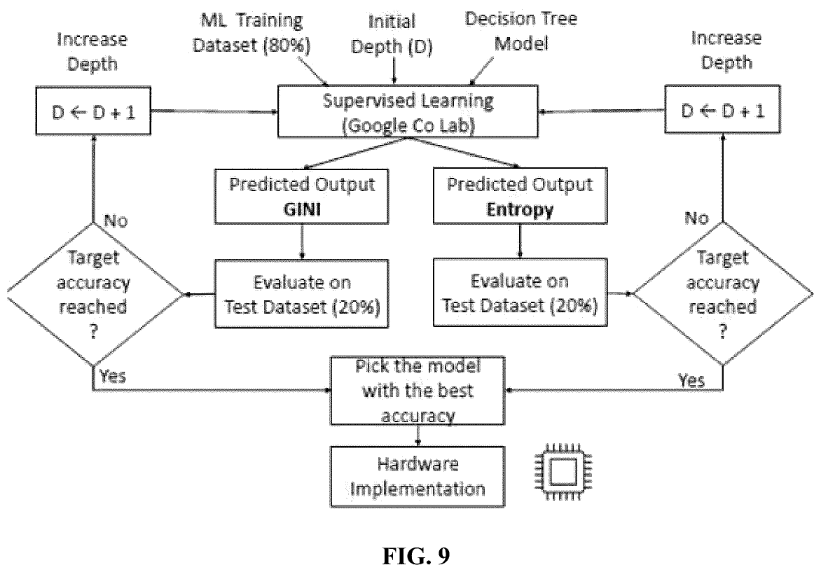

FIG. 10 is an example three-level H-structure, according to some embodiments.

FIG. 11 illustrates an example bit-slice architecture, according to some embodiments.

FIG. 12 illustrates an example layout of a bit-slice, according to some embodiments.

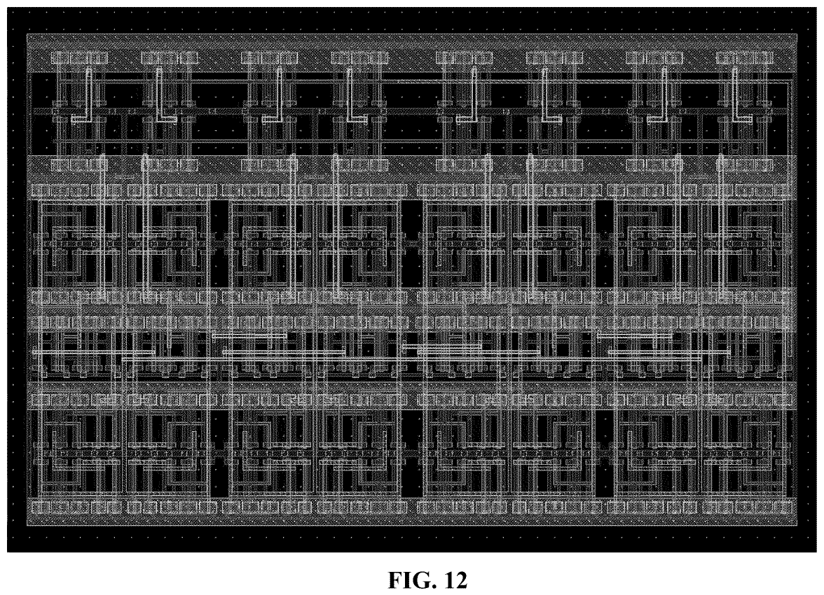

FIG. 13 illustrates an example bit-slice diagram with IO, according to some embodiments.

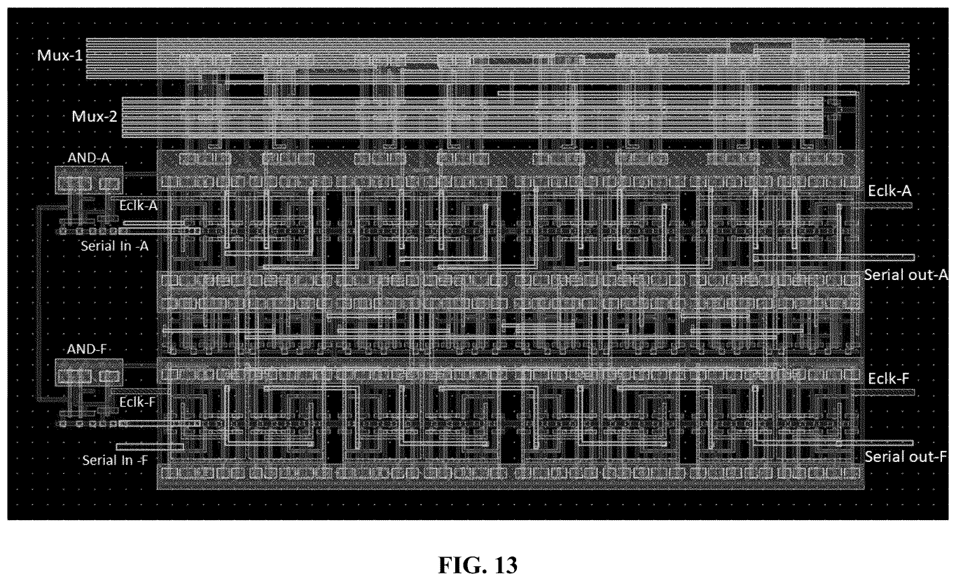

FIG. 14 is a diagram illustrating an example H-architecture for a two-level decision tree model, according to some embodiments.

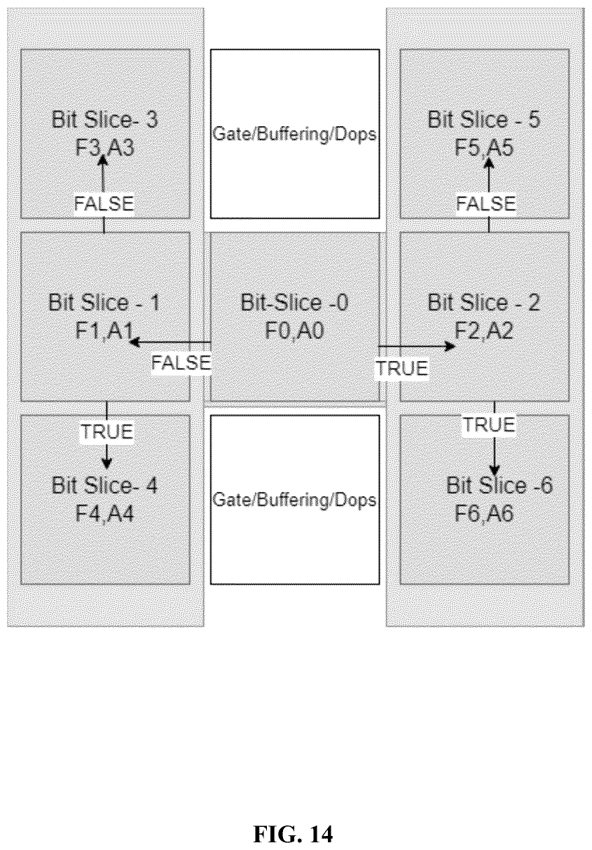

FIG. 15 illustrates an example layout of an H-architecture for a two-level decision tree model, according to some embodiments.

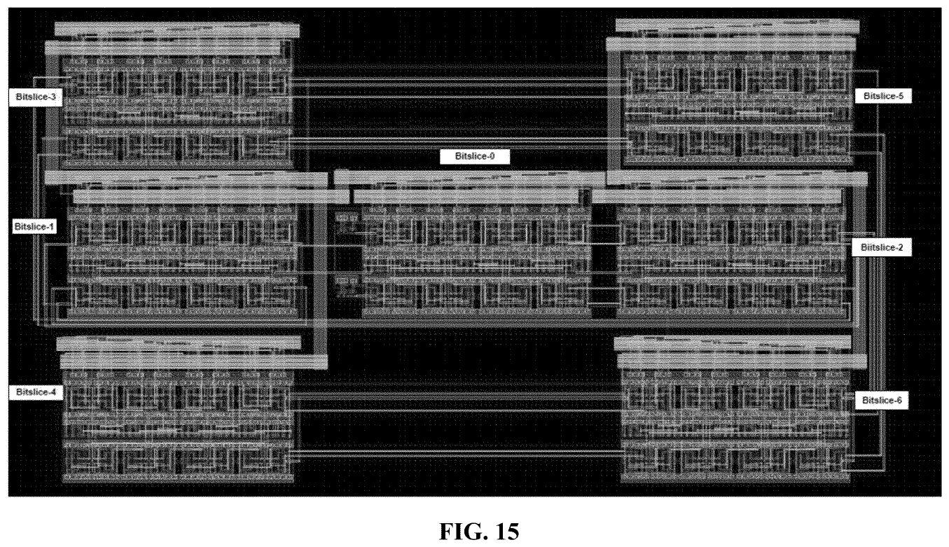

FIG. 16 is a diagram illustrating an order sequence for loading inputs into bit-slices, according to some embodiments.

FIG. 17 is an example mapping of an Iris decision tree model to a three-level H-architecture, according to some embodiments.

FIG. 18 is an example h-architecture layout for a three-level decision tree model, according to some embodiments.

FIG. 19 is an example circuit schematic for power gating circuitry, according to some embodiments.

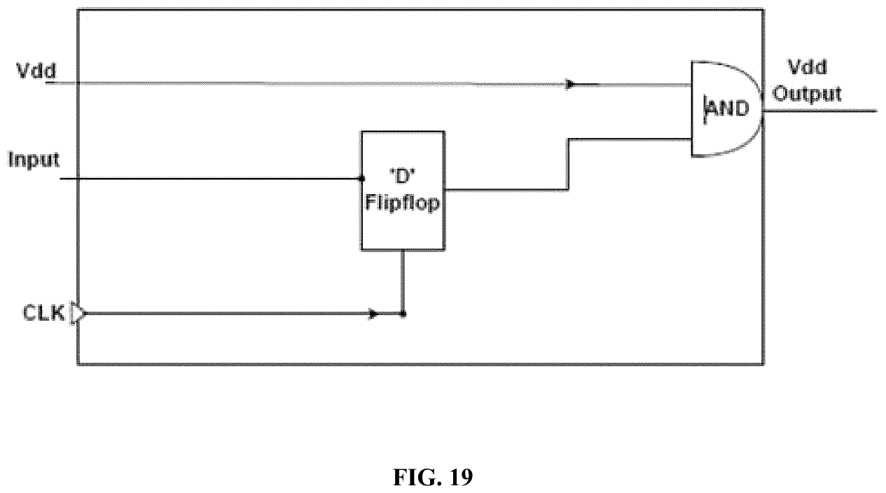

FIG. 20 is an example h-architecture for a five-level decision tree model, according to some embodiments.

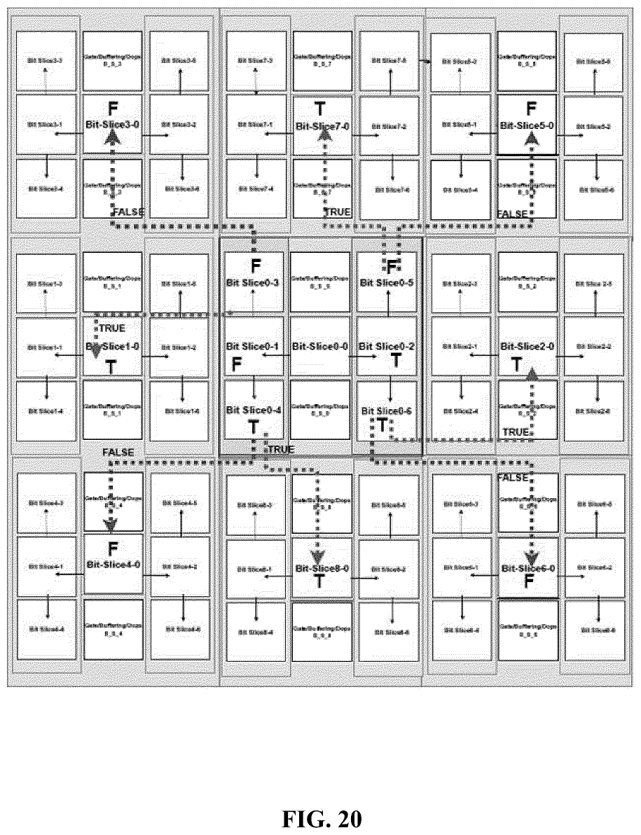

FIG. 21 is a flowchart of an example experimental set-up, according to some embodiments.

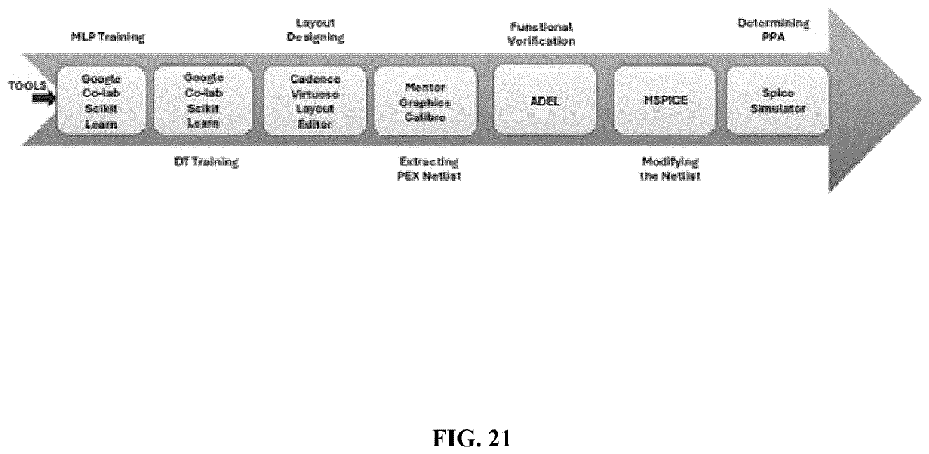

FIG. 22 is an example three-stage decision tree model for an Iris dataset, according to some embodiments.

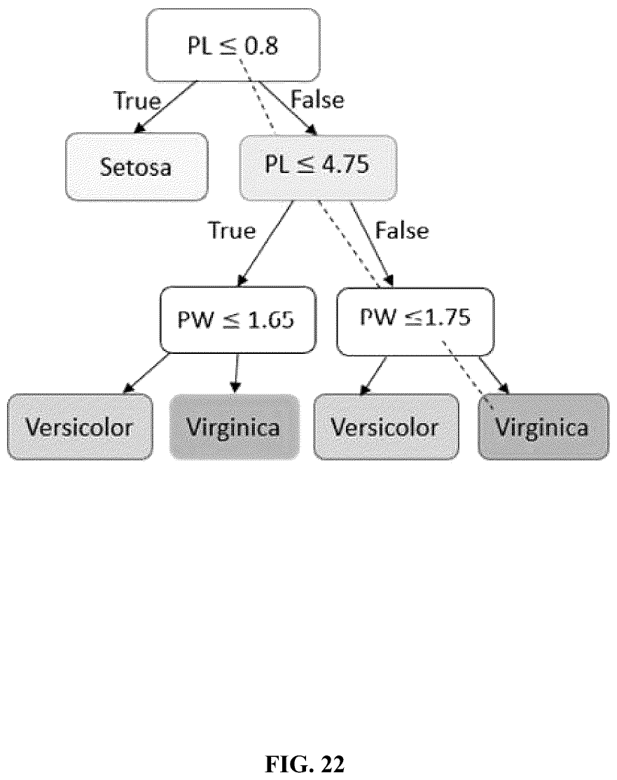

### DETAILED DESCRIPTION

The detailed description set forth below in connection with the appended drawings is intended as a description of various configurations and is not intended to represent the only configurations in which the subject matter described herein may be practiced. The detailed description includes specific details to provide a thorough understanding of various embodiments of the present disclosure. However, it will be apparent to those skilled in the art that the various features, concepts and embodiments described herein may be implemented and practiced without these specific details. In some instances, well-known structures and components are shown in block diagram form to avoid obscuring such concepts.

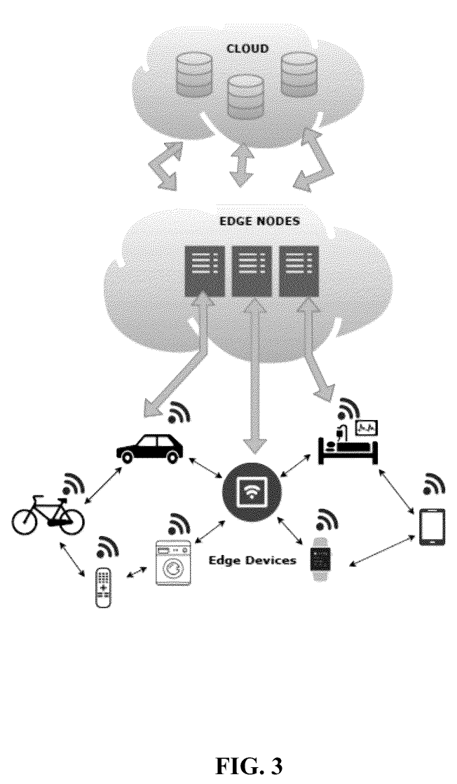

Decision trees (DTs) are a flexible supervised learning technique that may be applied to both classification and regression applications. Their structure is evident and follows a definite hierarchy. FIG. 3 provides an example of the decision-making process which is clearer and more a visual representation. These models operate by iteratively partitioning datasets into homogenous subgroups based on various criteria, such as information gain or gini impurity. This procedure generates a model that is capable of managing nonlinear interactions without the need for feature scaling. However, machine learning models are susceptible to overfitting and can exhibit strong sensitivity to even little variations in data. To solve these difficulties, one might utilize pruning processes or implement ensemble approaches like random forests. Decision trees are widely employed in several industries, including banking, healthcare, and retail, because of their efficient management of both numerical and categorical data.

During the training of a decision tree, every node, including the root and internal nodes, is split into two paths: a left-hand path and a right-hand path. The division is dependent upon a distinct discrete function that is derived from the attributes of the input data. Labels are exclusively assigned to the leaf nodes only based on information derived from the original training data. An essential component of training decision trees is determining the most effective splitting measure function for each internal node, excluding the leaf nodes. Within this specific framework, the optimal splitting function was established based on the concept of information gain (IG).

$$G ( E , A ) = H ( E ) - H ( E \vert A ) , \qquad ( 1 )$$

H(E) represents the entropy of dataset E, while H(E|A) signifies the conditional entropy of dataset E with respect to the attribute A.

Entropy estimates the level of uncertainty associated with the label values in the samples in a dataset. Increased entropy is directly proportional with higher uncertainty. The CART algorithm utilizes the concept of Gini Index (GI), which has parallels to the concept of entropy. Similar to entropy, GI is positively correlated with the degree of uncertainty. The CART technique was employed to train the datasets.

Initially, the input data and its attributes are introduced at the root node, where the splitting condition is assessed. If the condition is met, the data proceeds to the left node with a ‘1’ result; otherwise, it's directed to the right node with a ‘0’ result, concluding the evaluation at depth 0. This process recurs at subsequent levels, with results being combined and passed along the target path. The sequence continues until it reaches a leaf node, where the data's label is retrieved to finalize the Decision Tree classification.

The deployment of decision trees in machine learning is a series of steps that try to partition the dataset into more refined subsets based on specified criteria, with the goal of achieving the utmost precision in predictions or classifications. The first phase in constructing a decision tree is selecting the feature that best partitions the dataset into distinct categories. These measurements, such as Gini Impurity, Information Gain, or Gain Ratio, are utilized to estimate the efficacy of a feature in categorizing the data.

The dataset is partitioned into subgroups according to the selected characteristic. The division can be either binary or multi-way, depending on the nature of the feature, whether it is categorical or continuous. The two previous processes are iteratively applied to every subset that is generated. The recursion continues until one of the termination requirements is satisfied. This scenario may occur if the subset reaches a specific maximum depth, a given minimum number of samples are gathered, or if the splitting criterion does not show any improvement.

Once the required requirements for termination are met, the leaf nodes are generated. In a classification tree, the leaf node represents the class that has obtained the largest number of votes from the samples contained in that particular node. Pruning is a technique that may be used to reduce overfitting in decision trees. The process entails removing portions of the tree that provide limited contribution to the final model. To do this, one can eliminate branches of minimal relevance or combine nodes that do not significantly enhance the accuracy of the model.

### Example Decision Tree Layout Generation Process

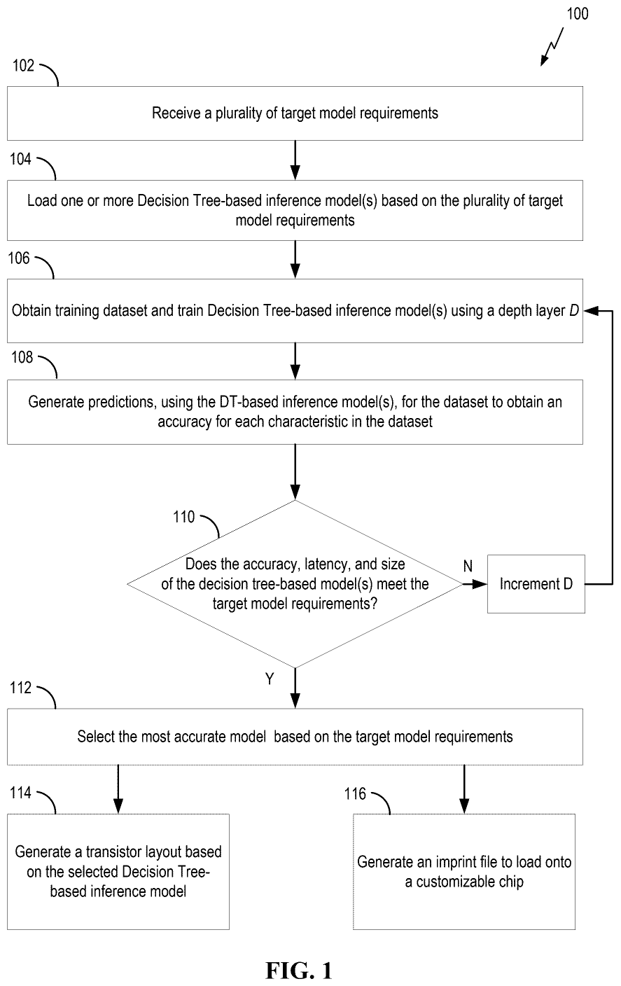

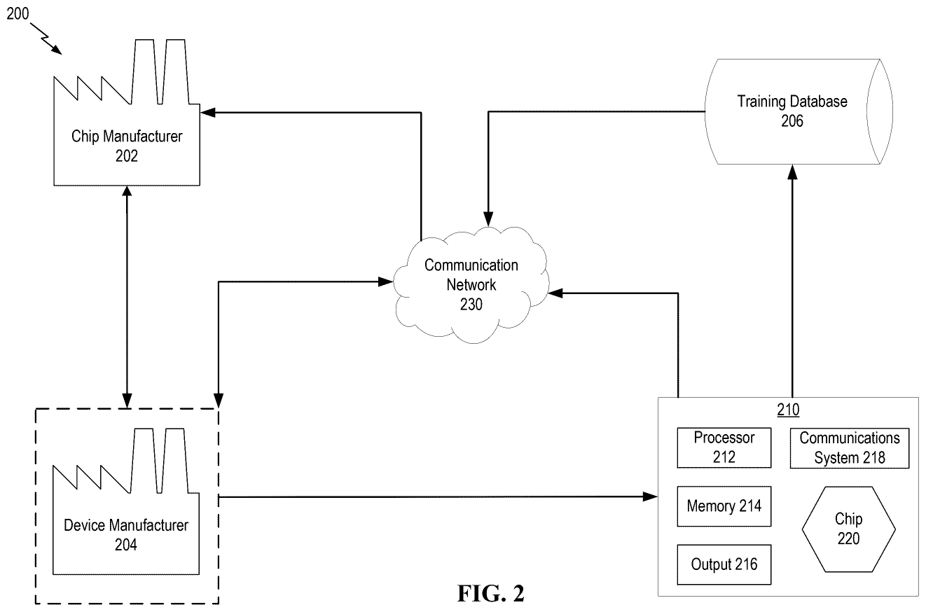

FIG. 1 is a flow diagram illustrating an example process 100 for generating a decision tree layout model, according to some embodiments. As described below, a particular implementation can omit some or all illustrated blocks, techniques, or steps, may be implemented in some embodiments in a different order, and may not require some illustrated features to implement all embodiments. In some examples, the systems and devices in connection with FIG. 2 can be used to perform all or part of example process 100. However, it should be appreciated that other suitable processing hardware for carrying out the operations or features described below may perform process 100.

At block 102, process 100 receives a plurality of target model requirements. The plurality of target model requirements can include a size of a model (e.g., maximum storage available to store a model), a latency or processing requirement, an accuracy threshold, a number of output classes, or the like. In some examples, the plurality of target model requirements may correspond to benchmarks established by other types of edge computing methods, such as a multi-layer perceptron. The target model may further define a rank or prioritization associated with each requirements, which may be utilized when comparing two or more decision tree-based inference models.

At block 104, process 100 loads one or more decision tree-based inference model(s) based on the target model requirements. A variety of types of decision tree models may be utilized, depending upon the nature of a desired implementation or task, attributes of the run-time data and anticipated deployment/run-time data, and computational environment. In some embodiments, the one or more decision tree-based inference models may include decision tree-based models such as Classification and Regression Trees (CART), Reduced-Error Pruned Decision Trees, Extremely Randomized Trees (Extra Trees), Hoeffding Trees for streaming data, or ensembles such as Random Forest and Gradient-Boosted Decision Trees (e.g., LightGBM, XGBoost). For example, the one or more decision tree-based inference model(s) may meet one or more of the target model requirements obtained at block 102.

At block 106, process 100 obtains a training dataset and trains the decision tree-based inference model using a depth layer D. In some examples, before the dataset is used to train the decision tree-based inference model, it may be pruned or preprocessed. For example, the training dataset may include data from a sensor, which can include a plurality of labels and categories of data that may not be relevant to the desired task or prediction. Preprocessing may involve data normalization, feature scaling, noise reduction, windowing, pruning irrelevant information, and outlier removal, thereby ensuring that the input data is consistent and suitable for analysis. The dataset may be collected from multiple sources, including real-world sensors, historical logs, and synthetic datasets generated through augmentation techniques. In some embodiments, process 100 may reference a library of datasets with various labels, such as acoustic data labeled with a variety of sound classifications, electric signals output by various physical sensors (e.g., electrodes, vibration sensors, accelerometers, and other similar devices that may be utilized in wearable, IoT, and other resource-constrained or edge systems, etc.) labeled with various domain-specific labels (e.g., activity classification, disease states, etc.). In other embodiments, process 100 may receive a new dataset specific to the given classification task. In further embodiments, process 100 may combine a general library (e.g., of acoustic data labeled as sounds) with a new dataset of specific sensor data (e.g., acoustic data labeled as a given sound(s) of interest, like a griding gear, doorbell, animal sound, etc.) of the same modality, and may in some circumstances weight the specific data higher (e.g., where there is a data imbalance). Thus, preprocessing may also be utilized to conform different datasets for combination.

In some examples, the training the decision tree-based inference model may include a training phase, where a plurality of tree parameters (i.e., settings or hyperparameters that control how the tree is constructed) are fine-tuned to prevent over-fitting. For example, the training may take into account the target model parameters, to ensure the model does not exceed any maximum requirements and therefore limit the model's ability to be further implemented in a device. The depth D may represented a length of a path from the root node to a leaf node of the decision tree. For example, a decision tree may ‘split’ at a node, therefore creating a layer and adding to the depth D.

At block 108, process 100 generates predictions, using the decision tree-based inference model, for the dataset to obtain an accuracy for each characteristic in the dataset. In some examples, the prediction may correspond to the type of data used to train the model. For example, the training dataset used at block 106 may include a plurality of sensor readings of air quality (e.g., a particulate matter measurement, an ozone level, a nitrogen dioxide level, a sulfur dioxide level, etc.). Therefore, the generated prediction may be an air quality index value, and a corresponding confidence level.

At block 110, process 100 determines if the accuracy, latency, and size of the decision tree-based inference model(s) meets the target model requirements. If the accuracy, latency, and size does not meet the requirements, the depth layer D is incremented. Once the requirements are met, the process 100 continues to block 112.

At block 112, process 100 selects the most accurate model based on the target model requirements, if more than one decision tree-based inference model was loaded at block 104. In some examples, more than one of the decision tree-based inference models may meet the requirements obtained at block 102. Therefore, the rank or prioritization associated with each requirement may be used to select a model. For example, if two or more of the models share a similar accuracy and latency levels, the model with the smaller size/memory requirements may be selected.

At block 114, process 100 generates a transistor layout based on the selected decision tree-based inference model. In some examples, the transistor layout may include an application-specific integrated circuit (ASIC) architecture for a specific application or task. In further examples, other architectures may be used based on a desired implementation or task. The transistor layout may include a H-structure, as further described below.

At block 116, process 100 generates an imprint file to load onto a customizable chip, based on the selected decision tree-based inference model. In some examples, the imprint file may include configuration information corresponding to physical components on a hardware device, such as field programmable gate array (FPGA). For example, the imprint file may be a file such as a. bit, .bin, .mcs, or the like. The imprint file may further include timing and routing files, device constraint files, netlist files, or the like.

### Example Decision Tree Inference Model Implementation System

FIG. 2 is a block diagram conceptually illustrating a system 200 for implementing a decision tree inference model on a chip 220, according to some embodiments. The chip may be implemented on a device 210. The device 210 can be an internet of things (IoT) edge device, such as a single-board computer, a computing chip, a router, a camera, or any suitable computing device. Thus, the processes described in FIGS. 2 and 3 may be tied to training and running hybrid data analysis models for a specific “local” sensing device.

A chip manufacturer 202 may create an FPGA-style or a dedicated ASIC chip. The chip manufacturer 202 may create chips are varying sizes, speeds, power consumptions, and functionalities. For example, the chip manufacturer 202 may produce a general purpose FPGA, a high performance FPGA, a low power FPGA, a system-on-chip FPGA, a rad-tolerant FPGA, an application specific FPGA, a high speed FPGA, or the like. The chips produced at the chip manufacturer 202 may be designed for use in specific industries such as communications, automotive, environmental, industrial, aerospace, or the like.

The decision tree inference model may begin as a generic decision tree classifier model provided to a chip by the chip manufacturer 202. In some examples, the chip manufacturer 202 may generate or load decision tree software onto a chip, including underlying architecture, such as logic blocks, programmable interconnections, I/O elements, etc. associated with the decision tree model. For example, the decision tree inference model may be a generic classifier model that may be further customized to provide a prediction tool for a specific application by a device manufacturer 204 who receives a chip from the chip manufacturer 202.

The device manufacturer 204 may be an original equipment manufacturer (OEM) that integrates chips received from the chip manufacturer 202 into a system or device 210. In some examples, the device manufacturer 204 may update an existing decision tree inference model uploaded to a chip at the chip manufacturer 202. For example, the device manufacturer 204 may select data from a training database 206 specific to predictions to be executed by, and sensors implemented into, a device 210. The device manufacturer may further create a hardware or imprint file specific to the device 210, and upload onto the chip 220.

In other examples, the chip manufacturer 202 may distribute a chip without implementing it onto a device, therefore bypassing the device manufacturer 204. For example, the chip 220 may be a stand alone chip, not associated with a computing device 210.

The computing device 210 can be used to perform prediction using a connected sensor or data received. For example, the sensor can be an integrated or connected sensor, such as motion data, force data, temperature data, air quality data, vibration or acoustic data, various electrical signal measurements, or the like. In further embodiments, the data may be higher order data such as a heart disease dataset, a breast cancer dataset, a lung cancer dataset, a fetal health dataset, or any other suitable dataset for which classifications and/or predictions will be made. For example, the dataset can include an image set (e.g., a video, stream, or timeseries), a medical record, X-ray data, electrical signal data, weather readings, LiDAR or depth sensor data, or any other suitable data for classification. In other examples, the dataset can include one or more features or vectors extracted from the sensor data. The computing device 210 can receive the dataset, whether from a sensor or as stored in a database, via communication network 230 and a communications system 218.

In some embodiments, the processor 212 can be any suitable hardware processor or combination of processors, such as a central processing unit (CPU), a graphics processing unit (GPU), an application specific integrated circuit (ASIC), a field-programmable gate array (FPGA), a digital signal processor (DSP), a microcontroller (MCU), etc.

The computing device 210 can further include a communications system 218. The communications system 218 can include any suitable hardware, firmware, and/or software for communicating information over the communication network 240 and/or any other suitable communication networks. For example, the communications system 218 can include one or more transceivers, one or more communication chips and/or chip sets, etc. In a more particular example, the communications system 218 can include hardware, firmware and/or software that can be used to establish a Wi-Fi connection, a Bluetooth connection, a cellular connection, an Ethernet connection, etc.

The computing device 210 can receive or transmit information and/or any other suitable system over a communication network 230. In some examples, the communication network 230 can be any suitable communication network or combination of communication networks. For example, the communication network 230 can include a Wi-Fi network (which can include one or more wireless routers, one or more switches, etc.), a peer-to-peer network (e.g., a Bluetooth network), a cellular network (e.g., a 3G network, a 4G network, a 5G network, etc., complying with any suitable standard, such as CDMA, GSM, LTE, LTE Advanced, NR, etc.), a wired network, etc. In some embodiments, communication network 230 can be a local area network, a wide area network, a public network (e.g., the Internet), a private or semi-private network (e.g., a corporate or university intranet), any other suitable type of network, or any suitable combination of networks. Communications links shown in FIG. 2 can each be any suitable communications link or combination of communications links, such as wired links, fiber optic links, Wi-Fi links, Bluetooth links, cellular links, etc.

In some examples, the computing device 210 can further include an output 216. The output 216 can include a set of output pins to output a prediction or classification. In other examples, the output 216 can include a display to output a prediction indication. In some embodiments, the display 216 can include any suitable display devices, such as a computer monitor, a touchscreen, a television, an infotainment screen, etc. to display a report containing a classification or prediction. In further examples, the prediction or classification can be transmitted to another system or device over the communication network 230.

### Example Embodiments and Experiments

To assess the viability of Decision Trees (DTs) in edge computing, both Multilayer Perceptrons (MLP) and DTs were trained on four datasets. Initially, MLPs were trained to establish a benchmark of high accuracy, which then served as the target for the DT models. The process involved using the scikit-learn framework within Google Co-lab to input training data, initial tree depth, and desired accuracy. Both GINI and Entropy were explored as criteria for DT development to ascertain the most accurate tree. The training process classifies data through a tree structure comprising decision and leaf nodes. During the training phase, the tree parameters were fine-tuned to prevent over-fitting, which can adversely affect the algorithm's performance. While software implementations of DT training can be time-consuming, hardware implementations offer increased parallelism, reducing execution time. The DT method begins by choosing the root feature and then repeatedly divides the data into subsets according to comparable qualities, continuing until leaf nodes are reached. To guide the traversal for class label assignment, prediction is carried out by comparing the record characteristics to the root. After obtaining the desired precision, hardware integration began.

In designing the custom ASIC architecture, the bit-slices were strategically placed in an H structure, drawing inspiration from its widespread use in clock topology. This configuration, where bit-slices represent the nodes of the H-tree structure, was specifically chosen for its proven efficacy in minimizing skew and latency. The adoption of this structure aimed to achieve efficient and reliable data propagation to each node within the ASIC.

The choice is motivated by maintaining high-speed data processing while minimizing delays and discrepancies in data handling. This architecture not only leverages the inherent advantages of the H-structure in reducing signal integrity issues but also enhances the scalability and flexibility of the ASIC design, ensuring it meets the demanding requirements of modern digital applications.

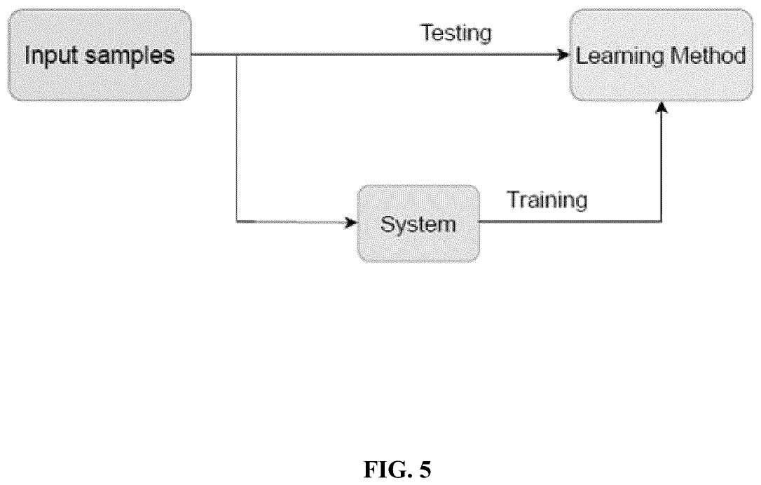

Bit Slice Architecture: The bit-slice architecture FIG. 5 consists of two 8-bit shift registers (F, A), an 8-bit Comparator, two 8-bit Mux (‘Mux-1’ and ‘Mux-2’) and two 2-input AND gates (‘AND-F,’ ‘AND-A’) for the enabled clock connection, which governs the loading of inputs to the shift registers. The clock signal is given as a common input to both AND gates, with the second input being ‘Enable A’ and ‘Enable F,’ respectively. ‘Enable A’ is kept high for the clock input to propagate to shift register A until all the attribute and classification values are loaded into respective bit-slices, and then ‘Enable A’ is turned low. Similarly, ‘Enable F’ is kept low until all attribute values are loaded, and then it is made high for the feature values to be loaded to each bit slice. After loading is done, the 8-bit comparator, compares the A and F values, resulting in an output that drives the select line of ‘Mux-1,’ which selects the respective true and false paths. The ‘Mux-2’ has two modes of operation controlled by asserting mode signals. When the mode is asserted high, the circuit behaves as a leaf node, and classification label values can be stored in it, whereas when the mode is asserted low, it behaves as a normal comparator, which takes the input from the Mux-1 output and decides true and false paths.

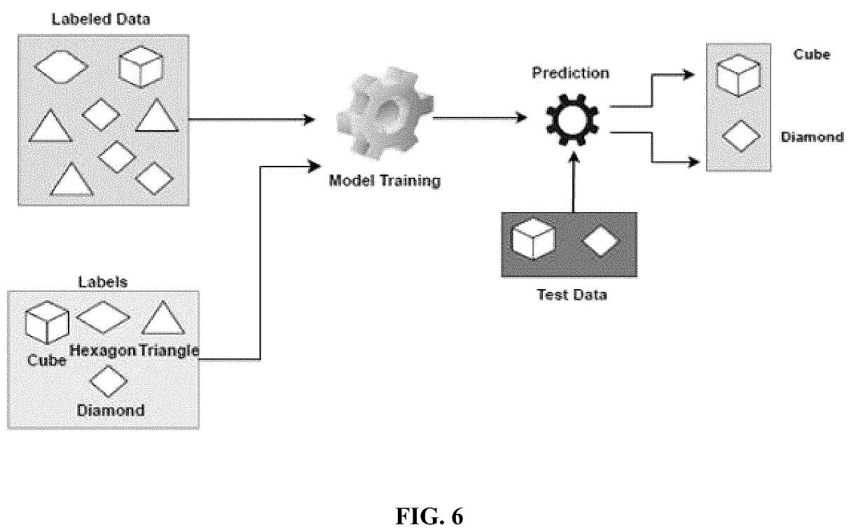

FIG. 6 shows the layout designed and implemented in the Cadence Virtuoso Layout editor in 0.5 μm CMOS technology node. It consists of the device layers with the interconnects that can work as a stand-alone bit-slice circuit. The components are strategically placed w.r.t internal connections and further integration of slices. Here, two multiplexers are on top, followed by a comparator sandwiched between the two serial in and serial out input registers. The buses are routed to carry inputs and outputs. The IO interface bus system consists of 7 different buses. Three are used for interfacing with neighboring bit-slices, of which two are the outputs of Mux-1 that connect the true and false paths to the neighboring bit-slices, and the other one is the output bus. Four others are the dedicated global buses for transferring the serial inputs (attribute and feature) values and the enabled clock connections (Eclk-A, Eclk-F) to each register. The buffer circuitry is responsible for buffering the global signals. A pair of inverters were used as buffers within the layout at each stage to increase the signal strength. The strategic placement of the bit-slices and buffer circuits makes this an area-optimized design.

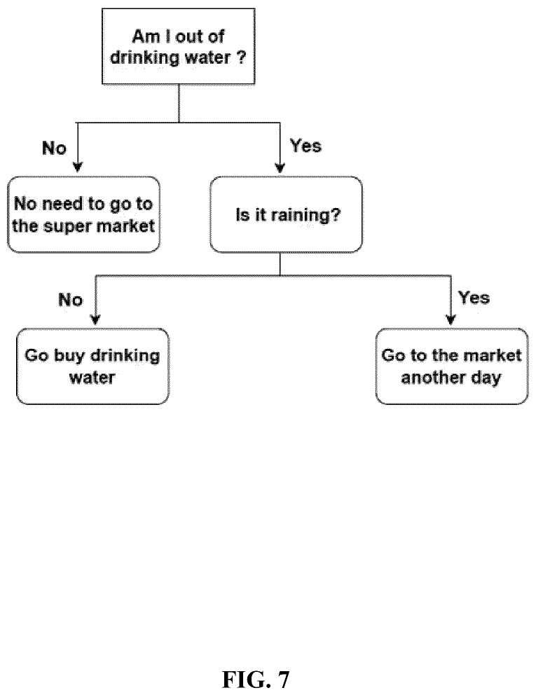

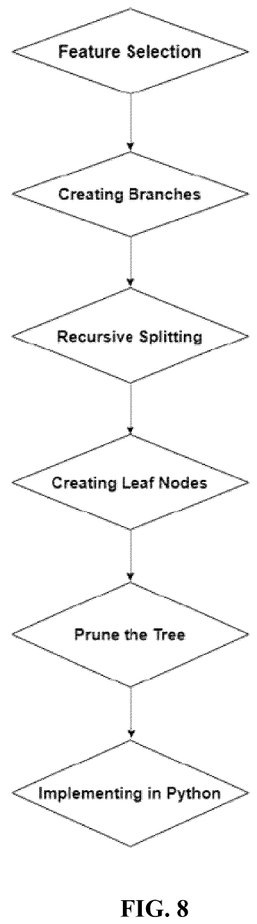

The floorplan of a 2-level DT is shown in FIG. 7, consisting of 7 nodes with 7 bit-slices interconnected w.r.t. true and false paths in an H structure minimizing timing violations. The two vacant places in the first and third rows are used for buffer circuits. FIG. 8 shows the layout of the 2-level H architecture for the above DT model. The design's functionality is verified using the ADEL (Analog Design Environment) simulation tool.

Programming and Operation: In the custom bit-sliced architecture, each bit-slice has two modes of operation, which can be controlled by asserting mode signals. When the mode is asserted high, the circuit behaves as a leaf node, and classification label values can be stored in it, whereas when the mode is asserted low, it behaves as a normal comparator, which decides true and false paths. The design processes the trained datasets for classification through two operational phases. Initially, in the programming phase, attribute values are assigned to bit slices along with leaf classification values. In the inference phase, the feature values are loaded serially for comparison at each bit slice, resulting in a final classification label at the root node.

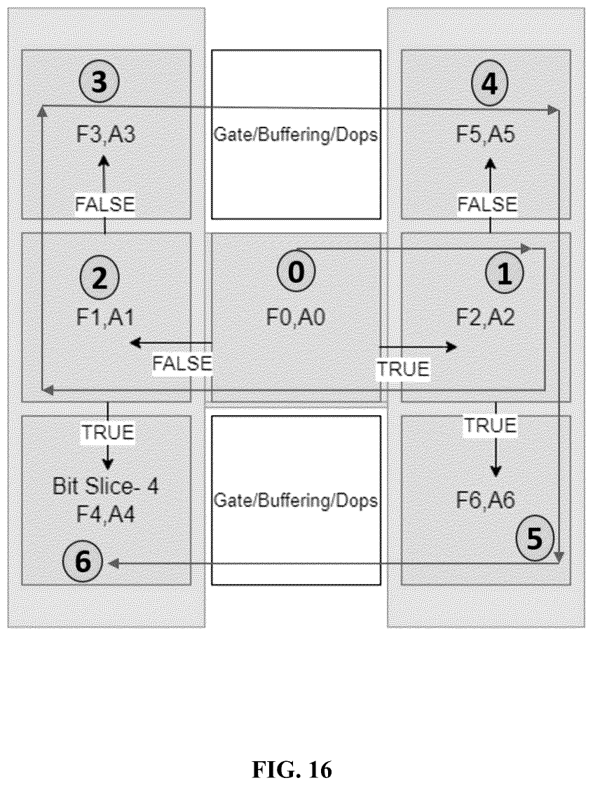

At first, when the enable input of the AND gate connected to the Register-A (Enable-A) is set to high, the clock propagates through the register for the values to be loaded to each bit-slice until all the attribute and classification values are loaded at their respective bit-slices in the order starting from (F0, A0) following the path from ‘0’ along the blue line, until ‘6’ (F4, A4), as shown in FIG. 16. Then, it is triggered low to cut the clock to the attribute register. During the real-time phase, the enabled input (Enable-F) is triggered high for the clock to propagate through ‘Register-F’. Subsequently, inferencing takes place by loading the feature values for comparison at each bit slice, resulting in classification at the output Mux-2.

Depending on the comparison result, the output is determined; if the comparison is true, then it follows the true path, which connects bitslice-0 and bitslice-2 resulting in bitslice-2 output at Mux-2 at bitslice-0. Similarly, when the comparison is false, it follows the false path, which connects bitslice-0 and bitslice-3 with bitslice-3 output at Mux-2 at bitslice-0. This process of comparison continues up to the leaf node, with the final results being observed at Mux-2 in bitslice-0.

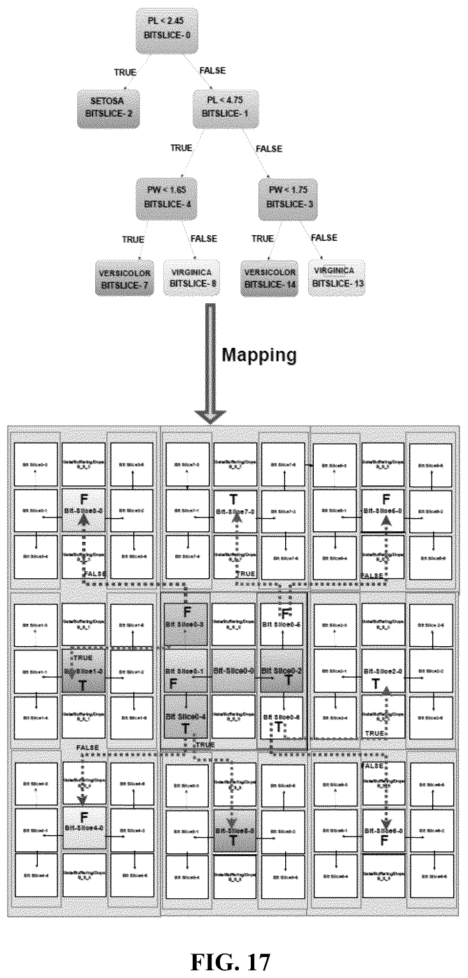

Mapping of Iris Decision Tree Model to H-Architecture: FIG. 17 shows the mapping of Iris DT model with a max depth of 3 to a 3-Level H-structure. The nodes of the Iris tree model, from the root node until the leaf classification, are mapped to bit-slices in the H-structure, starting from the centre of the H-tree and moving along the vertical lines w.r.t. true and false paths. For ease of understanding, each bit-slice in the H-structure has been color-matched with corresponding nodes in the Iris DT model. The feature values i.e., Petal Length (PL) and Petal Width (PW), are compared with the attribute values (0.8, 4.75, etc.) in the respective nodes at each level to determine the traversal of the tree to result in the classification values (Setosa, Versicolor, and Virginica) at the leaf nodes. For the 3-level H-structure the attribute registers enable input is set high for 3600 ns (number of bit-slices*register bitwidth*clock period). In this model, the number of bit-slices is 15, the bitwidth is 8, and the clock period is 30 ns. Thus, 15*8*30=3600 ns can be needed to load the attribute and classification label values.

Following this, the feature register's enable input is toggled high for the next 3600 ns for all the feature inputs to load and compared at each bit-slice, leading to the output of a classification label from mux2 in bit-slice-0 with a propagation delay of 78 ns, operating at 33.33 MHz and consuming 14.30 mW of power.

FIG. 17 is a 3-level H-Architecture that is mapped to the 3-level Iris DT model. Here, only 9 bit-slices are used during the computation, as the 3-level Iris DT model consists of only 9 nodes, which are colored-matched, and the remaining nodes, with no color, are unused for this DT model and thus waste power. To alleviate this, a power gating circuit is introduced for each bit-slice to pass the global clock only through the bit-slices that are active during the computation.

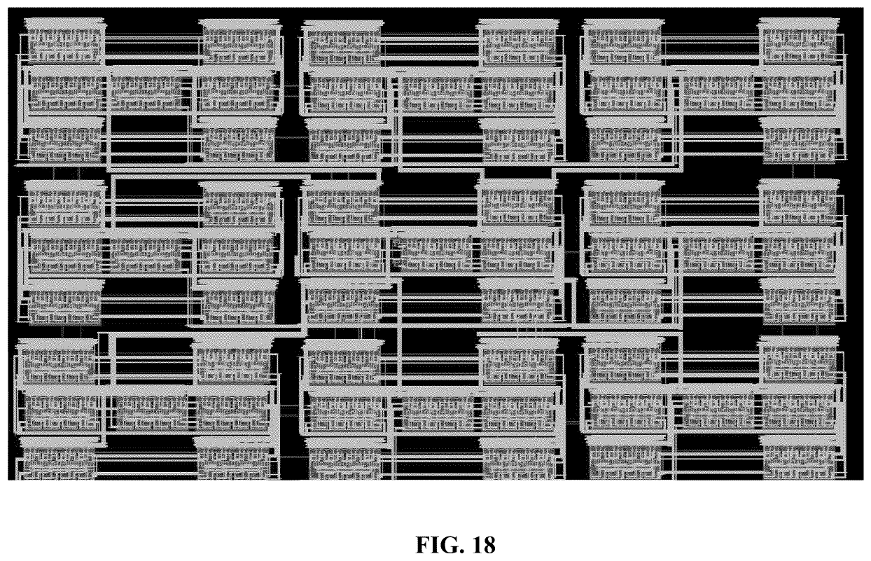

This was achieved by using FIG. 18, which receives the global VDD and common clock. Each power gating circuit is responsible for propagating the Vdd to the respective bit slices. The control is given through the input to the flip-flop, which is kept high until all the inputs are loaded and then make it low during computation. Each bit-slice will have a power gating circuit that can be accommodated within the cell allocated for the gates and buffers on the first and third rows within the H-structure.

Scalable Architecture: The scaling is done by connecting the 2-Level Integrated Slice in the N×N array, with the primary input being given to the i=j location. In FIG. 18, the scaling of the ‘5-Level DT’ is shown with the primary input given to the ‘2-Level Integrated Slice’ located at the center. Here, the root node of the tree is mapped to bit slice-0 and the programming is done similar to a 2-level H-structure. It is further connected to neighboring 2-level bit slices in a clock-wise manner, with the end nodes (bit slice 0-(3, 5, 6, 4)) connected to the center node of bit-slices (1, 3, 7, 5, 2, 6, 8, 4) respectively according to true and false paths denoted by blue and red arrows in the figure. From there, the traversal is with respect to the 2-level H-structure. It can be further scaled to 8, 11, 14 levels, and so on using the same technique.

Experimental Results: The layout implementations for the DT model are created with the Cadence Virtuoso Layout Editor in 0.5 μm CMOS technology node. On a DRC (Design Rule Check) clean layout, Parasitic Extraction (PEX) is performed using the Mentor Calibre tool. The extracted netlist was then converted into Hspice format, allowing us to evaluate the designlΓçÖs performance comprehensively. For functional verification of the design, the Analog Design Environment Tool (ADEL) was used, where transient analysis is carried out to inspect the outputs in the generated waveforms. Synopsys HSPICE simulator is used to measure the average power consumption and the worst-case delay.

TABLE 1
Hardware Design Attributes of Custom ASIC.

| | No. of | Area | Avg. Power | Worst-case |
|---|---|---|---|---|
| Levels | Transistors | (μm²) | (mW) | delay (ns) |
| 0 | 4,860 | 40,299 | 3.18 | 14 |
| 1 | 14,364 | 121,242 | 7.10 | 29 |
| 2 | 33,372 | 384,319 | 10.16 | 60 |
| 3 | 71,028 | 934,241 | 14.30 | 78 |
| 5 | 107,034 | 1,400,740 | 22.58 | 123 |

Performance Metrics of Custom ASIC: Table 1 outlines the design specifications of a custom ASIC tailored for machine learning applications across five levels, emphasizing scalability and efficiency. At the initial level 0, the ASIC design is compact, comprising 4,860 transistors within an area of 40,299 μm 2, and it achieves power efficiency with an average consumption of just 3.18 mW, alongside a worst-case delay of 14 ns. As the number of levels increase, the number of transistors and the area increase non-linearly. Level 1 DT uses 14,364 transistors and level 3 uses 71,028 transistors, with corresponding areas of 121,242 μm 2 and 934,241 μm², respectively. Power consumption rises modestly in correlation with complexity, from 7.10 mW in level 1 to 14.30 mW in level 3. This ASIC's design evolution demonstrates significant area and power savings potential, making it well-suited for a range of machine learning datasets where resource efficiency is paramount.

TABLE 2
Performance Metrics for 3-Level Architecture

| | Input | ML Dataset | Avg. Power | Inference time |
|---|---|---|---|---|
| Dataset | Features | Size | (mW) | delay (ns) |
| Iris | 4 | 150 | 10.7 | 7200 |
| Breast Cancer | 11 | 569 | 38.18 | 14,400 |
| Credit Card | 28 | 30,000 | 38.07 | 14,400 |
| Heart Disease | 13 | 303 | 38.20 | 14,400 |
| Raisin | 7 | 900 | 38.00 | 14,400 |
| Fetal Health | 21 | 2,126 | 16.03 | 7,653 |
| Liver | 11 | 583 | 16.28 | 2,098 |
| Diagnostic | | | | |

Table 2 compares the performance of the custom ASIC on multiple datasets. These datasets, which vary in the quantity of features and instances, include Iris, Breast Cancer, Credit Card, Heart Disease, Raisin, Fetal Health, and Liver Diagnostic. For each data set, the average power consumption and inference time was evaluated. The Iris dataset, has 150 instances and 4 features. The average power usage was 10.7 mW, and the inference delay was 1,080 μs. Similarly, in the Breast Cancer dataset with 11 features and 569 instances, the average power consumption was 14.83 mW, with an inference delay of 72,000 μs. The average power consumption across all datasets was between 10.7 and 16.28 mW, and the related inference delays were between 1,080 μs and 72,000 μs. These results highlight how crucial it is to take accuracy and computational economy into account when implementing machine learning models in contexts with limited resources.

It presents a comparative study of the power consumption used and the efficiency of power consumption. Before using power gating, level 1 has 14,364 transistors. After implementing power gating, there is a 3.25% increase in the number of transistors, resulting in a total of 14,824 transistors. However, this increase in transistor count leads to an 18.3% improvement in power efficiency. The average power consumption is reduced from 7.101 mW to 5.8 mW. The pattern of increasing transistor count and decreasing power consumption continues in levels 2 and 3.

Level 2 exhibits a precise rise of 4.20% in transistor count and a significant decrease of 18.8% in power consumption. On the other hand, level 3 demonstrates a little increase of 4.61% with the most considerable power optimization of 27.97%. The amount of power saved depends on the number of unused nodes in the decision tree.

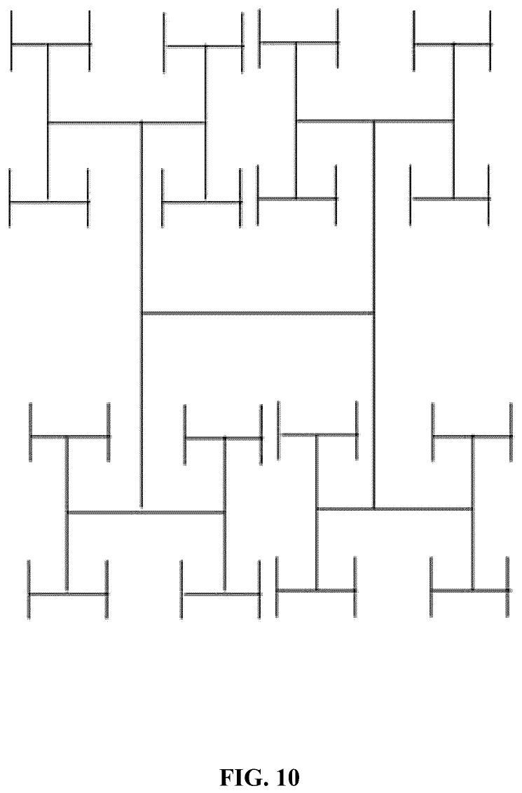

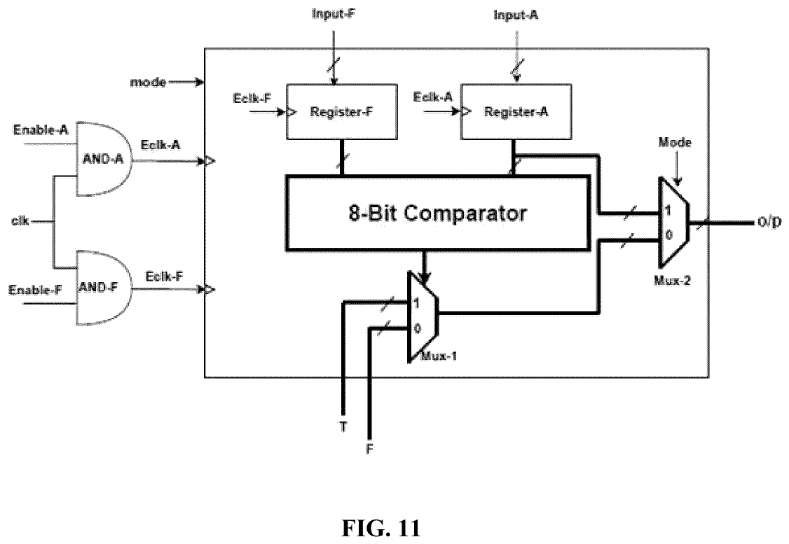

FIGS. 10 and 11 provide a concise overview of the impact of power gating on five levels of hierarchical design. It presents a comparative study of the power consumption used and the efficiency of power consumption. Before using power gating, level 1 has 14,364 transistors. After implementing power gating, there is a 3.25% increase in the number of transistors, resulting in a total of 14,824 transistors. However, this increase in transistor count leads to an 18.3% improvement in power efficiency. The average power consumption is reduced from 7.101 mW to 5.8 mW. The pattern of increasing transistor count and decreasing power consumption continues in levels 2, 3 and 5.

In the foregoing specification, implementations of the disclosure have been described with reference to specific example implementations thereof. It will be evident that various modifications may be made thereto without departing from the broader spirit and scope of implementations of the disclosure as set forth in the following claims. The specification and drawings are, accordingly, to be regarded in an illustrative sense rather than a restrictive sense.

What is claimed is:

1. A method of imprinting a decision tree layout model onto a classification chip, the method comprising:
receiving a plurality of target model requirements;
loading one or more decision tree-based inference models based on the plurality of target model requirements;
obtaining a training data;
training the one or more decision tree-based inference models using a depth layer D;
generating a plurality of predictions corresponding to the training data using the one or more decision tree-based inference models;
determining a plurality of prediction parameters associated with the plurality of predictions;
comparing the plurality of prediction parameters to the plurality of target model requirements;
selecting an inference model from the one or more decision tree-based inference models based on the comparison; and
generating a transistor layout based on the selected inference model.

2. The method of claim 1, further comprising:
incrementing the depth layer D upon determining that the plurality of prediction parameters do not meet the plurality of target model requirements.

3. The method of claim 1, further comprising:
generating an imprint file corresponding to the selected inference model; and
loading the imprint file onto the classification chip.

4. The method of claim 1, wherein the plurality of target model requirements comprises one or more of a desired accuracy, a desired latency, or a maximum size.

5. A classification chip for performing a decision-tree prediction model, the chip comprising:
a real-time clock;
a plurality of bit-slices, each bit slice of the plurality of bit-slices comprising:
a pair of 8-bit shift registers configured to receive a first input;
a pair of 2-input AND gates configured to receive a clock signal and a second input;
an 8-bit comparator connected to the pair of 8-bit shift registers and configured to compare a first output from the pair of 8-bit registers;
a first 8-bit multiplexer connected to the 8-bit comparator and configured to define a plurality of true and false paths; and
a second 8-bit multiplexer connected to the first 8-bit multiplexer and one 8-bit shift registers of the pair of 8-bit shift registers and configured to define a plurality of classification labels.
